(19) United States
(12) Patent Application Publication
(10) Pub. No.: US 2020/0176648 A1
(43) Pub. Date: Jun. 4, 2020

(54) LIGHT EMITTING PACKAGE STRUCTURE AND METHOD OF MANUFACTURING THE SAME

(71) Applicants: LITE-ON OPTO TECHNOLOGY (CHANGZHOU) CO., LTD., Changzhou City (CN); LITE-ON TECHNOLOGY CORPORATION, Taipei City (TW)

(72) Inventors: CHIH-YUAN CHEN, NEW TAIPEI CITY (TW); TIEN-YU LEE, TAIPEI CITY (TW); CHIEN-TUNG HUANG, NEW TAIPEI CITY (TW); WEI-LUN TSAI, NEW TAIPEI CITY (TW)

(21) Appl. No.: 16/592,877

(22) Filed: Oct. 4, 2019

(30) Foreign Application Priority Data
Nov. 30, 2018 (CN) 201811453487.3

(51) Int. Cl. H01L 33/52; H01L 33/50; H01L 33/46

(52) U.S. Cl. CPC H01L 33/52; H01L 33/46; H01L 33/502

(57) ABSTRACT

A light emitting package structure includes: a light emitting chip, an encapsulant covering the light emitting chip and having an anti-adhesion upper surface and an anti-adhesion surrounding surface. A method of manufacturing a light emitting package structure is further provided and includes: configuring a plurality of light emitting chips on a temporary carrier; forming an encapsulant to cover the plurality of light emitting chips; cutting the encapsulant to form the independent light emitting package structure; and surface treating the cut encapsulant such that the encapsulant has an anti-adhesion upper surface and an anti-adhesion surrounding surface.

### CROSS-REFERENCE TO RELATED PATENT APPLICATION

This application claims the benefit of priority to China Patent Application No. 201811453487.3, filed on Nov. 30, 2018 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light emitting package structure and a method of manufacturing the same, and more particularly to a surface treated light emitting package structure and a method of manufacturing the same.

### BACKGROUND OF THE DISCLOSURE

As light emitting diodes (LEDs) have advantages such as power saving, long life, environment-friendly and small size, light emitting components have been widely used in electronic devices and optical devices in recent years.

In conventional packaging technology, a silicone material is used as the main packaging material for its characteristics such as excellent weather resistance, heat resistance and optical properties. However, since the silicone material is viscous and easily adheres to a carrier tape, the yield from mounting technology is decreased.

Chip scale package (CSP) is a new type of LED package. Specifically, the structure of the CSP merely includes a light emitting chip having five sides covered by silicone, so that the adhesion issue of the silicone material occurs often in the CSP. Common anti-adhesion treatments in the conventional art involve such as using fluorine anti-adhesive agents, silicone having higher hardness, antistatic packaging tape, and cover tape and carrier designed with bumps. However, the silicone thus treated often ends up with uneven coating, without coating on the sides, and having higher hardness, so as to be easily broken or have poor reliability. Therefore, how the surface adhesion of CSP can be reduced to improve the mounting yield has become one of the important issues to be solved in the industry.

### SUMMARY OF THE DISCLOSURE

In response to the above-referenced technical inadequacies, the present disclosure provides a light emitting package structure and a method of manufacturing the same, so as to improve on issues relating to poor mounting yield due to CSP surface adhesion, reduce the loss of rejected materials, and reduce customer complaints.

In one aspect, the present disclosure provides a light emitting package structure including a light emitting chip and an encapsulant. The encapsulant covers the light emitting chip and has an anti-adhesion upper surface and an anti-adhesion surrounding surface after surface treatment. A light beam generated by the light emitting chip passes through the encapsulant along an emitting path.

In one aspect, the present disclosure provides a method of manufacturing a light emitting package structure. The method includes: configuring a plurality of light emitting chips on a temporary carrier; forming an encapsulant to cover the plurality of light emitting chips; cutting the encapsulant to form the independent light emitting package structure; and surface treating the cut encapsulant such that the encapsulant has an anti-adhesion upper surface and an anti-adhesion surrounding surface.

One of the beneficial effects of the present disclosure is that with the technical solution of “the encapsulant having an anti-adhesion upper surface and an anti-adhesion surrounding surface,” the light emitting package structure and the method of manufacturing the same provided by the present disclosure can reduce the surface adhesion of the light emitting package structure and improve the mounting yield.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a perspective view of a light emitting package structure according to an embodiment of the present disclosure.

FIG. 2A is a cross sectional view of the light emitting package structure taken along line IIA-IIA in FIG. 1 according to an embodiment of the present disclosure.

FIG. 2B is a cross sectional view of the light emitting package structure taken along line IIA-IIA in FIG. 1 according to another embodiment of the present disclosure.

FIG. 2C is a cross sectional view of the light emitting package structure taken along line IIA-IIA in FIG. 1 according to another embodiment of the present disclosure.

FIG. 2D is a cross sectional view of the light emitting package structure taken along line IIA-IIA in FIG. 1 according to still another embodiment of the present disclosure.

FIG. 2E is a cross sectional view of the light emitting package structure taken along line IIA-IIA in FIG. 1 according to yet another embodiment of the present disclosure.

FIG. 3 is a flowchart of a method of manufacturing a light emitting package structure according to the present disclosure.

FIG. 4 is a flowchart of the method of manufacturing the light emitting package structure according to the present disclosure.

FIG. 5 is a flowchart of the method of manufacturing the light emitting package structure according to the present disclosure.

FIG. 6 is a flowchart of the method of manufacturing the light emitting package structure according to the present disclosure.

FIG. 7 is a flowchart of the method of manufacturing the light emitting package structure according to the present disclosure.

FIG. 8A to FIG. 8D are flowcharts of the method of manufacturing the light emitting package structure according to the present disclosure.

FIG. 9A to FIG. 9E are flowcharts of the method of manufacturing the light emitting package structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

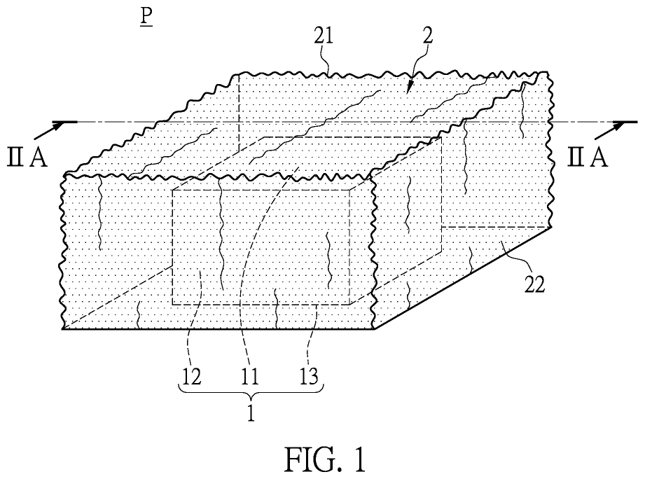

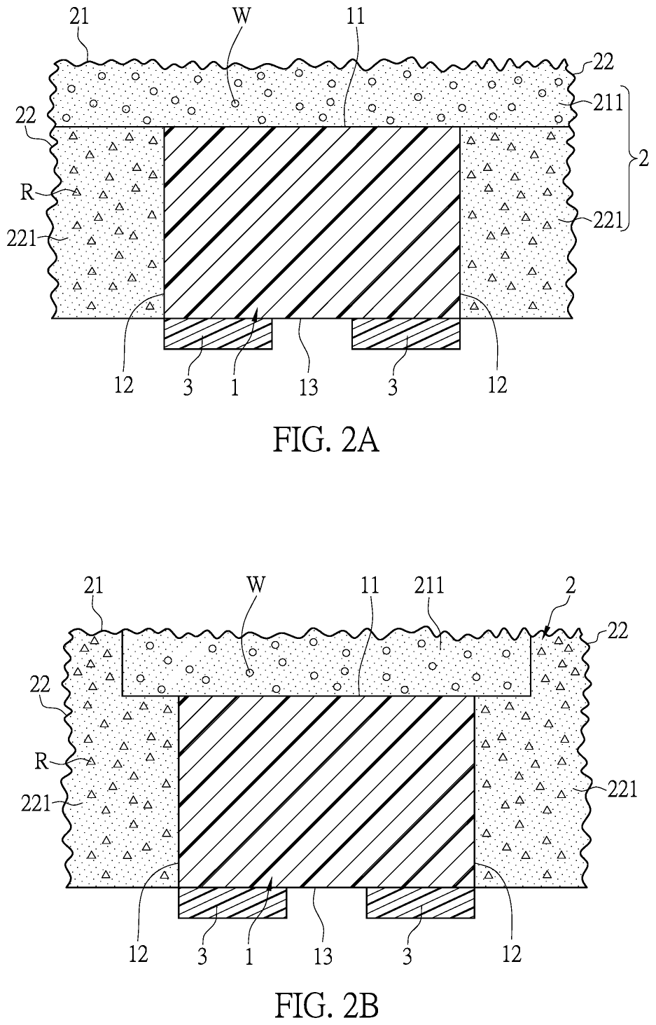

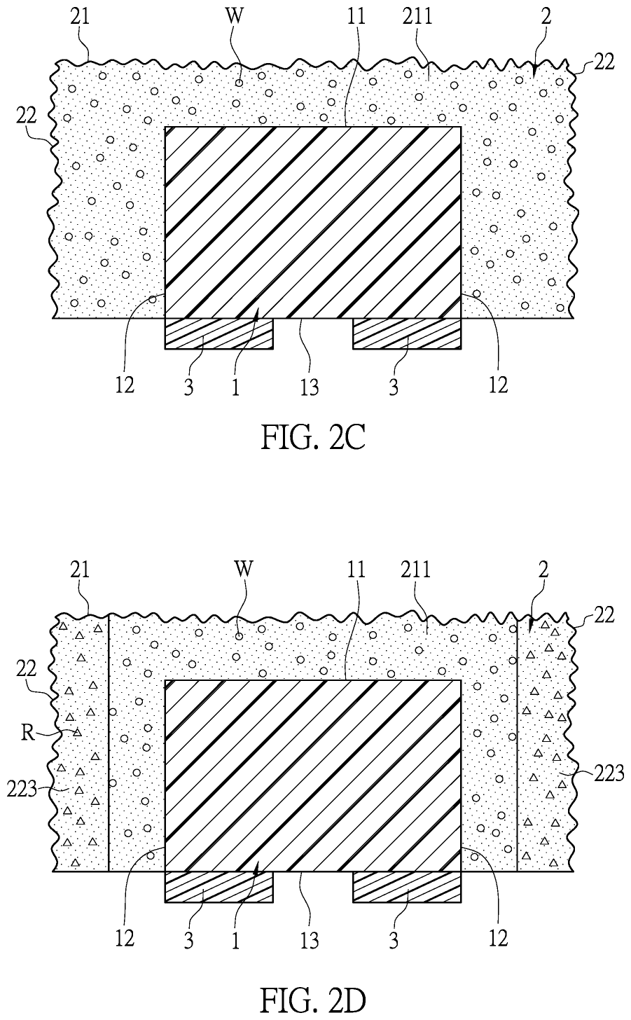

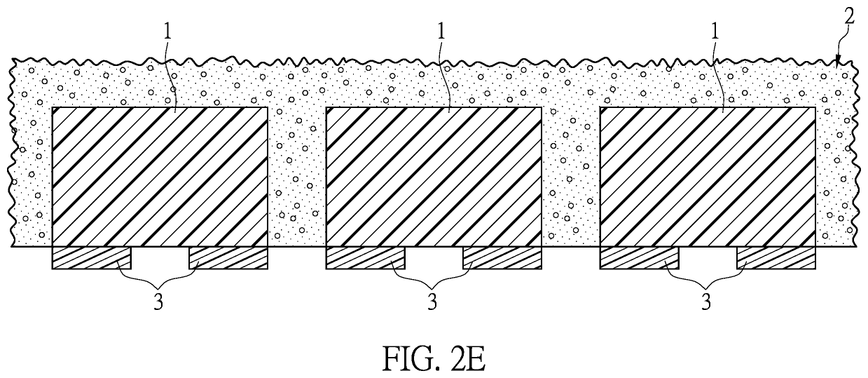

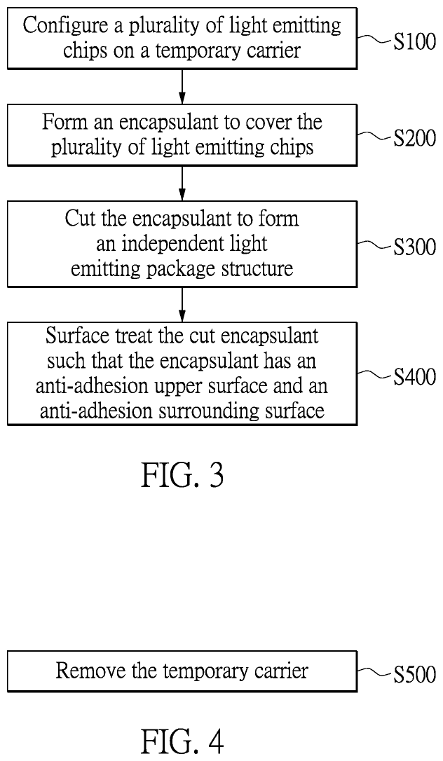

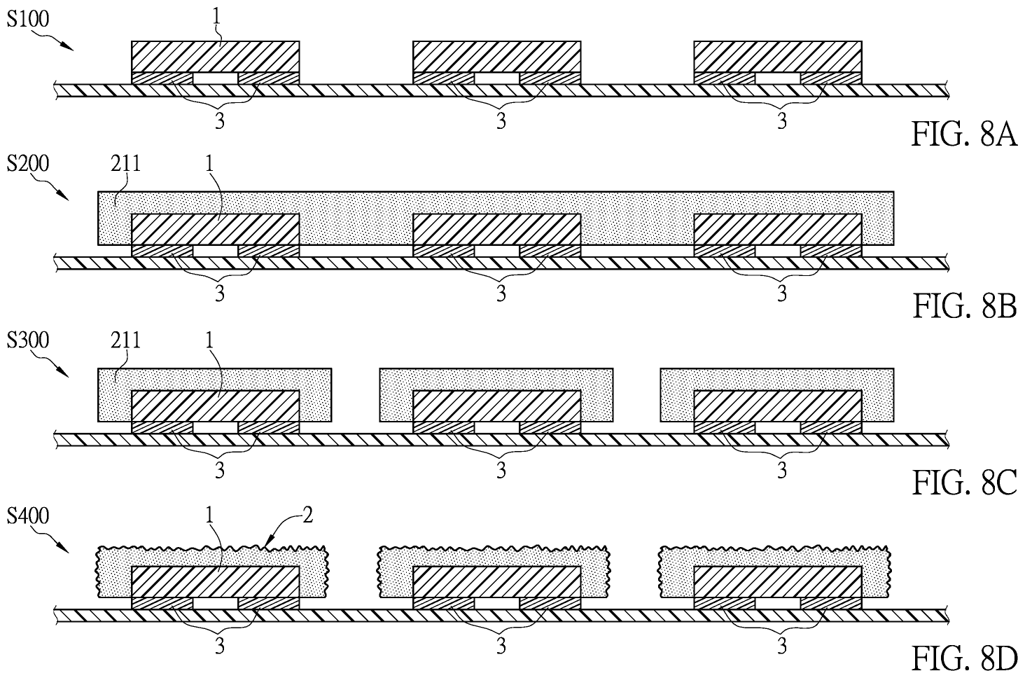

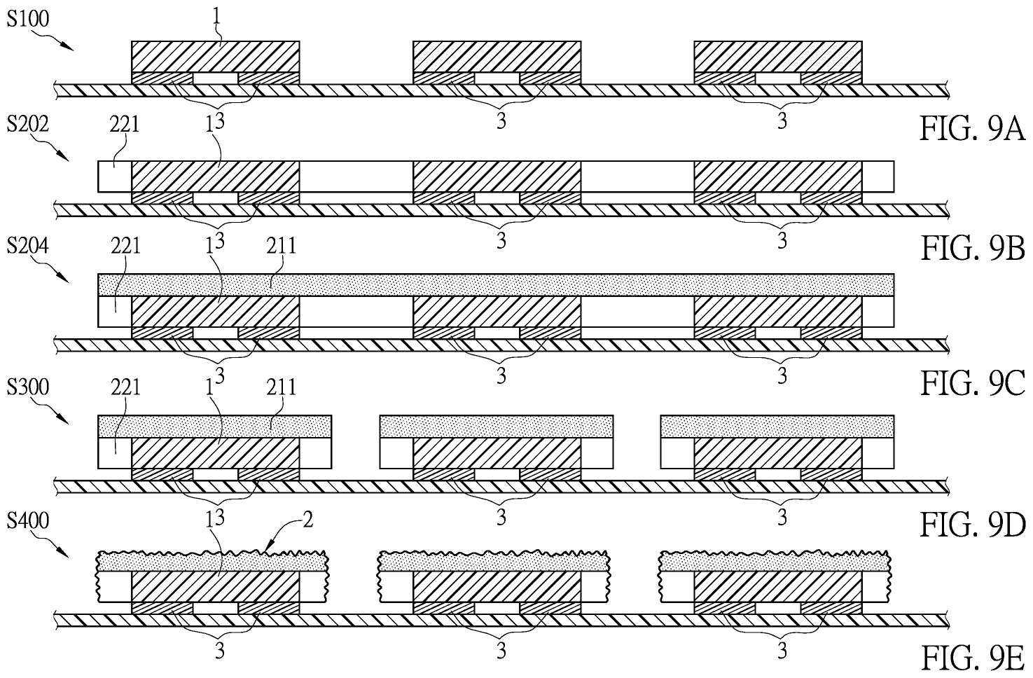

FIG. 1 to FIG. 2D are schematic views showing the structure of a light emitting package structure according to various embodiments of the present disclosure. FIG. 3 to FIG. 7 are flowcharts of a method of manufacturing a light emitting package structure according to the present disclosure. FIG. 8A to FIG. 8D and FIG. 9A to FIG. 9E are flowcharts of the method of manufacturing the light emitting package structure according to the present disclosure.

FIG. 1 shows a light emitting package structure P provided by an embodiment of the present disclosure. The light emitting package structure P includes a light emitting chip 1 and an encapsulant 2. The encapsulant 2 covers the light emitting chip 1 and has an anti-adhesion upper surface 21 and an anti-adhesion surrounding surface 22. A light beam generated by the light emitting chip 1 passes through the encapsulant 2 along an emitting path (not shown). The anti-adhesion upper surface 21 and the anti-adhesion surrounding surface 22 are obtained by surface treating.

Specifically, the light emitting chip 1 can be a six sided three-dimensional structure having a light emergent surface 11 and a lower surface 13 opposite to each other, and a surrounding surface 12 extending from the light emergent surface 11 to the lower surface 13. The encapsulant 2 can be a six sided three-dimensional structure having the anti-adhesion upper surface 21 corresponding to the light emergent surface 11 and the anti-adhesion surrounding surface 22 corresponding to the surrounding surface 12. In one embodiment, the anti-adhesion upper surface 21 is parallel to the light emergent surface 11, and the anti-adhesion surrounding surface 22 is parallel to the surrounding surface 12. Preferably, the encapsulant 2 completely covers the light emergent surface 11 and the surrounding surface 12 of the light emitting chip 1 and exposes the lower surface 13 of the light emitting chip 1.

In addition, the encapsulant 2 of the present disclosure can be in different designs such as in a convex shape, a concave shape or a planar shape so as to produce different optical effects, thereby increasing the diversity of light emitting patterns of the light emitting chip 1, and enhancing brightness and luminous efficiency.

More specifically, the anti-adhesion upper surface 21 and the anti-adhesion surrounding surface 22 are surface treated rough surfaces. Preferably, the anti-adhesion upper surface 21 and the anti-adhesion surrounding surface 22 are rough surfaces which have been surface treated entirely, and a roughness ratio of the anti-adhesion upper surface 21 to the anti-adhesion surrounding surface 22 is 0.009 to 0.75.

Further, FIG. 2A to FIG. 2D are cross sectional views of the light emitting package structure taken along line IIA-IIA in FIG. 1 according to different embodiments of the present disclosure.

FIG. 2A shows the light emitting package structure according to an embodiment of the present disclosure. The light emitting package structure includes the light emitting chip 1 and the encapsulant 2. The encapsulant 2 has the anti-adhesion upper surface 21 corresponding to the light emergent surface 11, and the anti-adhesion surrounding surface 22 corresponding to the surrounding surface 12. The encapsulant 2 includes a light transmissive layer 211 disposed on the light emergent surface 11 and a reflection layer 221 disposed on the surrounding surface 12. A wavelength conversion material W is mixed in the light transmissive layer 211, and a reflective material R is mixed in the reflection layer 221. More specifically, the anti-adhesion upper surface 21 and the anti-adhesion surrounding surface 22 are rough surfaces formed by surface treating the outer surfaces of the light transmissive layer 211 and the reflection layer 221. That is, the upper surface of the light transmissive layer 211 is the anti-adhesion upper surface 21, and side surfaces of the light transmissive layer 211 and the outer surface of the reflection layer 221 form the anti-adhesion surrounding surface 22. In addition, the lower surface 13 of the light emitting chip 1 further includes a conductive pad 3, and the number of the conductive pad 3 depends upon practical requirements. The encapsulant 2 is disposed on the outer surface of the light emitting chip 1 but does not cover the conductive pad 3 and the lower surface 13.

FIG. 2B shows the light emitting package structure according to another embodiment of the present disclosure. The light emitting package structure includes the light emitting chip 1 and the encapsulant 2. The encapsulant 2 has the anti-adhesion upper surface 21 corresponding to the light emergent surface 11 and the anti-adhesion surrounding surface 22 corresponding to the surrounding surface 12. The encapsulant 2 includes the light transmissive layer 211 disposed on the light emergent surface 11 and the reflection layer 221 disposed on the surrounding surface 12. The light transmissive layer 211 is further surrounded by the reflection layer 221. The wavelength conversion material W is mixed in the light transmissive layer 211, and the reflective material R is mixed in the reflection layer 221. More specifically, the anti-adhesion upper surface 21 and the anti-adhesion surrounding surface 22 are rough surfaces formed by surface treating the outer surfaces of the light transmissive layer 211 and the reflection layer 221. That is, in the embodiment shown in FIG. 2B, the light transmissive layer 211 and the partially upper surface of the reflection layer 221 form the anti-adhesion upper surface 21, and side surfaces of the reflection layer 221 form the anti-adhesion surrounding surface 22. In the same way, the lower surface 13 of the light emitting chip 1 further includes the conductive pad 3, and the number of the conductive pad 3 depends upon practical requirements. The encapsulant 2 is disposed on the outer surface of the light emitting chip 1 but does not cover the conductive pad 3 and the lower surface 13.

FIG. 2C shows the light emitting package structure according to another embodiment of the present disclosure. The light emitting package structure includes the light emitting chip 1 and the encapsulant 2. The encapsulant 2 includes the light transmissive layer 211 disposed on the light emergent surface 11 and surrounding the surrounding surface 12. The upper surface of the light transmissive layer 211 forms the anti-adhesion upper surface 21 corresponding to the light emergent surface 11, and the side surfaces of the light transmissive layer 211 form the anti-adhesion surrounding surface 22 corresponding to the surrounding surface 12. The wavelength conversion material W is mixed in the light transmissive layer 211. As mentioned above, the anti-adhesion upper surface 21 is formed by surface treating the light transmissive layer 211, and the anti-adhesion surrounding surface 22 is formed by the side surfaces of the light transmissive layer 211. In the same way, the lower surface 13 of the light emitting chip 1 further includes the conductive pad 3, and the number of the conductive pad 3 depends upon practical requirements. The encapsulant 2 is disposed on the outer surface of the light emitting chip 1 but does not cover the conductive pad 3 and the lower surface 13.

FIG. 2D shows the light emitting package structure according to still another embodiment of the present disclosure. The light emitting package structure includes the light emitting chip 1 and the encapsulant 2. The encapsulant 2 includes the anti-adhesion upper surface 21 corresponding to the light emergent surface 11 and the anti-adhesion surrounding surface 22 corresponding to the surrounding surface 12. The encapsulant 2 includes the light transmissive layer 211 disposed on the light emergent surface 11 and the reflection layer 223 surrounding the light transmissive layer 211. The wavelength conversion material W is mixed in the light transmissive layer 211 and the reflective material R is mixed in the reflection layer 223. Specifically, the outer surface of the encapsulant 2 formed by the light transmissive layer 211 and the reflection 223 further forms the anti-adhesion upper surface 21 and the anti-adhesion surrounding surface 22 by surface treating. That is, the upper surfaces of the light transmissive layer 221 and the reflection layer 223 form the anti-adhesion upper surface 21 and the side surfaces of the reflection layer 223 form the anti-adhesion surrounding surface 22. In the same way, the lower surface 13 of the light emitting chip 1 further includes the conductive pad 3, and the number of the conductive pad 3 depends upon practical requirements. The encapsulant 2 is disposed on the outer surface of the light emitting chip 1 but does not cover the conductive pad 3 and the lower surface 13.

Further, the light emitting package structure of the present disclosure has another embodiment as shown in FIG. 2E. In FIG. 2E, the encapsulant 2 covers the plurality of light emitting chips 1. That is, the plurality of light emitting chips 1 can be taken as one unit, and the specific implementation thereof is the same as that shown in FIG. 2A to FIG. 2D.

In the above descriptions, the upper surface corresponds to the surface of the light emergent surface 11 and the side surfaces correspond to the surrounding surface 12. The method of manufacturing and surface treating the light emitting package structure will be described later.

Moreover, the encapsulant 2 may further include a diffusion layer (not shown) as required, which can be disposed on the light transmissive layer 211 and/or the reflection layers 221 and 223. Specifically, the diffusion layer can be disposed on the upper surface of the light transmissive layer 211 (as shown in FIG. 2B or FIG. 2C), or the upper surface and the surrounding surface of the light transmissive layer 211 (as shown in FIG. 2C), or the upper surface of the light transmissive layer 211 and the outer surface of the reflection layer 221 (as shown in FIG. 2A), or the upper surfaces of the light transmissive layer 211 and the reflection layer 223 (as shown in FIG. 2D). Specifically, the diffusion layer can be silicon mixed with astigmatic substances such as SiO₂ or TiO₂ to increase propagation paths or reflection paths of light.

Specifically, the encapsulant 2 can be the light transmissive layer 211 formed by silicone mixed with the wavelength conversion material W or the light transmissive layer 211 with the structures of reflection layers 221 and 223 mixed with silicone and the reflective material R, or further including the structure of the diffusion layer. In other words, the encapsulant 2 can be a silicone material that is classified into a light transmissive layer, a reflection layer or a diffusion layer according to the material added therein. Based on the above, the encapsulant 2 is a surface treated rough surface, and FIG. 2A to FIG. 2D show the features of the anti-adhesion upper surface 21 and the anti-adhesion surrounding surface 22 after surface treatment.

A method of manufacturing a light emitting package structure is further provided in the present disclosure. Referring to FIG. 3 and FIG. 8A to FIG. 8D, the method includes: S100, configuring a plurality of light emitting chips on a temporary carrier, wherein in this embodiment each of the light emitting chips 1 further includes the conductive pad 3 disposed on the lower surface 13; S200, forming an encapsulant to cover the plurality of light emitting chips, without covering the conductive pad 3 and the lower surface 13; S300, cutting the encapsulant to form an independent light emitting package structure; and S400, surface treating the cut encapsulant such that the encapsulant has an anti-adhesion upper surface and an anti-adhesion surrounding surface.

In a specific embodiment of the method of the present disclosure, after the step of surface treating the encapsulant, the method further includes: S500, removing the temporary carrier. That is, the light emitting package structure having the light emitting chip 1, the encapsulant 2 and the conductive pad 3 is obtained.

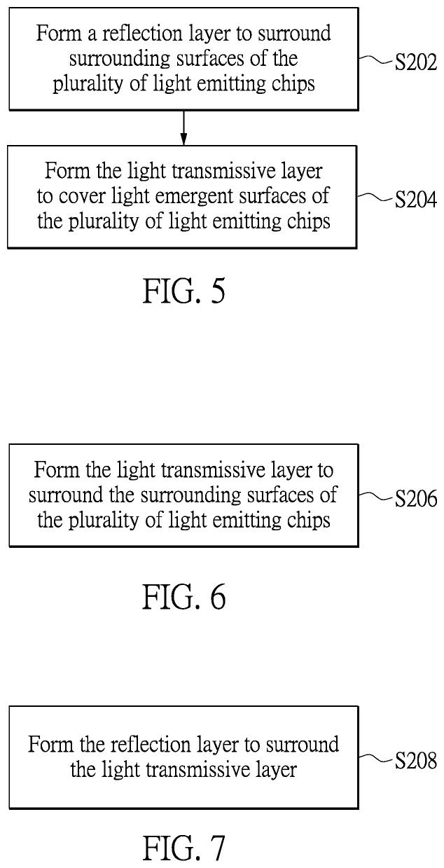

In addition, the step S200, forming an encapsulant to cover the plurality of light emitting chips, as shown in FIG. 5 and FIG. 9A to FIG. 9E, further includes: S202, forming the reflection layer 221 to surround surrounding surfaces of the plurality of light emitting chips, wherein a reflective material is mixed in the reflection layer 221; and S204, forming the light transmissive layer 211 to cover light emergent surfaces of the plurality of light emitting chips, wherein a wavelength conversion material is mixed in the light transmissive layer 211.

In FIG. 6 showing S200, forming an encapsulant to cover the plurality of light emitting chips, S200, further includes: S206, forming the light transmissive layer to surround the surrounding surfaces of the plurality of light emitting chips, wherein a wavelength conversion material is mixed in the light transmissive layer. In FIG. 7, after S206, forming the light transmissive layer, the method further includes: S208, forming the reflection layer to surround the light transmissive layer, wherein a reflective material is mixed in the reflection layer.

In addition, the step S200 of forming the encapsulant to cover the plurality of light emitting chips can further include a step as required: forming a diffusion layer.

In a specific embodiment, in S100, the light emitting chip 1 is disposed on the temporary carrier through the lower surface 13. Specifically, the temporary carrier can be a flexible film such as a blue tape, a UV tape, a film or a rigid additional circuit board, but is not limited thereto. In addition, the light emitting chip 1 further includes the conductive pad 3 disposed on the lower surface 13. The temporary carrier can be single sided adhesive or double sided adhesive, such that the light emitting chip can be directly disposed on the surface of the temporary carrier having adhesive properties to temporarily fix the light emitting chip and facilitate subsequent manufacturing steps.

In S200, forming an encapsulant to cover the plurality of light emitting chips, the light transmissive layer or the reflection layer is formed according to the foregoing descriptions. Specifically, gaps between the plurality of light emitting chips 1 and the temporary carrier are filled by the encapsulant 2.

In S300, cutting the encapsulant, the cutting can be performed on the temporary carrier by using a cutting tool, such as a laser-cutting device. However, the manner of forming the independent light emitting package structure is not limited to the above. Moreover the independent light emitting package structure can be formed by stamping and cutting the encapsulant 2, such that the plurality of light emitting package structures have gaps therebetween. It should be noted that the independent light emitting package structure may include one or more light emitting chips.

Specifically, the surface treatment in S400, can be physical processing, chemical etching or electrolytic etching. For example, a rough surface can be manufactured by a sanding or roughening tool or plasma treatment. More specifically, sanding (or grinding) is an abrasive machining process that uses powders or granules to grind the surface of the product; the roughening tool includes a trowel or a sandpaper to directly roughen the surface; plasma treatment is to clean the surface by using argon or hydrogen plasma. In addition, sandblasting can also be adopted in cooperation with an air gun and carborundum. In a dry or wet condition, carborundum or an abrasive material is sprayed onto the surface to be treated with a compressed gas to achieve surface roughening. It should be noted that in S300, the plurality of light emitting package structures have gaps formed therebetween, and in S400, the upper surface and the surrounding surface (such as side surfaces) of the encapsulant 2 are surface treated, so that the anti-adhesion upper surface 21 and the anti-adhesion surrounding surface 22 of the present disclosure can be obtained.

### Embodiment 1

Firstly, the plurality of light emitting chips are arranged and configured on the temporary carrier, and the silicone is mixed with the wavelength conversion material to serve as the encapsulant and to be disposed on the light emitting chip and the temporary carrier. At this time, the encapsulant is filled into the gaps between the plurality of light emitting chips, and the light transmissive layer is formed on the plurality of light emitting chips. A cutting tool is used to cut the encapsulant along a predetermined cutting path to obtain the plurality of independent light emitting package structures having the light emitting chip and the light transmissive layer. Then, argon (Ar) plasma is used to treat the surface of the light transmissive layer of the light emitting package structure at a frequency of 400 W for 12 minutes. Finally, the temporary carrier is removed.

### Embodiment 2

Firstly, the plurality of light emitting chips are arranged and configured on the temporary carrier, and the silicone mixed with the reflective material is disposed on the temporary carrier without covering the light emergent surfaces of the light emitting chips. The reflection layer is filled into the gaps between the plurality of light emitting chips. The silicone mixed with the wavelength conversion material is disposed on the reflection layer and the light emergent surfaces of the light emitting chips to form the light transmissive layer.

A cutting tool is used to cut the encapsulant along a predetermined cutting path to obtain the plurality of independent light emitting package structures having the light emitting chip, the reflection layer and the light transmissive layer. Then, a grinding machine is used to surface treat the surface of the light emitting package structure by grinding with alumina powders for 30 minutes. Finally, the temporary carrier is removed.

The values of roughness of the upper surface and surrounding surface of the light emitting package structures obtained in Embodiments 1 and 2 of the present disclosure before and after surface treatment are tested as shown in Table 1.

TABLE 1

| | | Before surface treatment | | | | After surface treatment | | | |
|---|---|---|---|---|---|---|---|---|---|
| | | SAD | R_{q} | Rₐ | Rₘₐₓ | SAD | R_{q} | Rₐ | Rₘₐₓ |
| | | (%) | (nm) | (nm) | (nm) | (%) | (nm) | (nm) | (nm) |
| Embodiment 1 | Upper surface | 0.0810 | 2.33 | 1.77 | 27 | 0.0208 | 4.26 | 3.21 | 62.4 |
| | Surrounding | 20.3 | 132 | 105 | 1055 | 42 | 347 | 275 | 2222 |
| | surface | | | | | | | | |
| Embodiment 2 | Upper surface | 0.0814 | 4.33 | 3.55 | 29.3 | 19.8 | 297 | 235 | 1867 |
| | Surrounding | 22.5 | 180 | 135 | 1454 | 48.1 | 480 | 362 | 2916 |
| | surface | | | | | | | | |

SAD(%): Selected area diffraction
Rq(nm): Root mean square roughness
Ra(nm): Arithmetic mean roughness
Rmax(nm): Maximum height roughness

One of the beneficial effects of the present disclosure is that with the technical solution of “the encapsulant having an anti-adhesion upper surface and an anti-adhesion surrounding surface,” the light emitting package structure and the method of manufacturing the same provided by the present disclosure can reduce the surface adhesion of the light emitting package structure and improve the mounting yield.

Further, the conventional light emitting package structure only has the surface treated upper surface so as to improve the light uniformity. With the anti-adhesion upper surface and the anti-adhesion surrounding surface, and along with the feature that “a roughness ratio of the anti-adhesion upper surface of the encapsulant to the anti-adhesion surrounding surface of the encapsulant is 0.009 to 0.75,” the light emitting package structure of the present disclosure can not only improve the light uniformity but effectively reduce the surface adhesion.

The method of manufacturing the light emitting package structure includes the step of “cutting the encapsulant” before surface treatment, such that the outer surface of the light emitting package structure of the present disclosure, after surface treatment, not only has the anti-adhesion upper surface, but also has “the anti-adhesion surface”, so that the present disclosure can effectively overcome the issue of the upper surface or the side surface adhering to a carrier tape causes poor yield of mounting technology.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light emitting package structure, comprising:
a light emitting chip; and
an encapsulant covering the light emitting chip and having an anti-adhesion upper surface and an anti-adhesion surrounding surface after surface treatment, a light beam generated by the light emitting chip passing through the encapsulant along an emitting path.

2. The light emitting package structure according to claim 1, wherein a roughness ratio of the anti-adhesion upper surface of the encapsulant to the anti-adhesion surrounding surface of the encapsulant is 0.009 to 0.75.

3. The light emitting package structure according to claim 1, wherein the light emitting chip has a light emergent surface and a surrounding surface, the anti-adhesion upper surface of the encapsulant corresponds to the light emergent surface, and the anti-adhesion surrounding surface of the encapsulant corresponds to the surrounding surface.

4. The light emitting package structure according to claim 3, wherein the encapsulant includes a light transmissive layer disposed on the light emergent surface and a reflection layer surrounding the surrounding surface, a wavelength conversion material is mixed in the light transmissive layer, and a reflective material is mixed in the reflection layer.

5. The light emitting package structure according to claim 4, wherein the light transmissive layer is surrounded by the reflection layer.

6. The light emitting package structure according to claim 3, wherein the encapsulant includes a light transmissive layer disposed on the light emergent surface, and a wavelength conversion material is mixed in the light transmissive layer.

7. The light emitting package structure according to claim 6, wherein the encapsulant includes a reflection layer surrounding the light transmissive layer, and a reflective material is mixed in the reflection layer.

8. The light emitting package structure according to claim 1, wherein the light emitting package structure further includes at least one conductive pad disposed on a lower surface of the light emitting chip, and the encapsulant does not cover the conductive pad and the lower surface.

9. A method of manufacturing a light emitting package structure, comprising:
configuring a plurality of light emitting chips on a temporary carrier;
forming an encapsulant to cover the plurality of light emitting chips;
cutting the encapsulant to form the independent light emitting package structure; and
surface treating the cut encapsulant such that the encapsulant has an anti-adhesion upper surface and an anti-adhesion surrounding surface.

10. The method according to claim 9, wherein each of the plurality of light emitting chips includes a lower surface, and at least one conductive pad is disposed on the lower surface; wherein, in the step of forming an encapsulant to cover the plurality of light emitting chips, the encapsulant does not cover the lower surface and the at least one conductive pad.

11. The method according to claim 9, wherein a roughness ratio of the anti-adhesion upper surface of the encapsulant to the anti-adhesion surrounding surface of the encapsulant is 0.009 to 0.75.

12. The method according to claim 9, wherein the surface treatment is physical processing, chemical etching or electrolytic etching.

13. The method according to claim 9, further comprising: removing the temporary carrier after surface treating the encapsulant.

14. The method according to claim 9, wherein the step of forming the encapsulant further includes:
forming a reflection layer to surround surrounding surfaces of the plurality of light emitting chips, a reflective material being mixed in the reflection layer; and
forming a light transmissive layer to cover light emergent surfaces of the plurality of light emitting chips, a wavelength conversion material being mixed in the light transmissive layer.

15. The method according to claim 14, wherein the light transmissive layer is surrounded by the reflection layer.

16. The method according to claim 9, wherein the step of forming the encapsulant further includes forming a light transmissive layer to surround surrounding surfaces of the plurality of light emitting chips and cover light emergent surfaces of the plurality of light emitting chips, and a wavelength conversion material is mixed in the light transmissive layer.

17. The method according to claim 16, wherein the step of forming the encapsulant further includes forming a reflection layer to surround the light transmissive layer, and a reflective material is mixed in the reflection layer.
